(19) United States
(12) Patent Application Publication
(10) Pub. No.: US 2025/0023544 A1
(43) Pub. Date: Jan. 16, 2025

(54) SURFACE ACOUSTIC WAVE DEVICE WITH SUPPRESSED EXCITATION OF SPURIOUS WAVES

(71) Applicant: WISOL CO., LTD., Osan-si (KR)

(72) Inventors: Yoshikazu KIHARA, Osan-si (KR); Hun Yong LEE, Osan-si (KR); Tae Hyun KIM, Osan-si (KR)

(21) Appl. No.: 18/760,378

(22) Filed: Jul. 1, 2024

(30) Foreign Application Priority Data
Jul. 14, 2023 (KR) 10-2023-0092041

(51) Int. Cl. H03H 9/02; H03H 9/25

(52) U.S. Cl. CPC H03H 9/02574; H03H 9/02559; H03H 9/25

(57) ABSTRACT

A surface acoustic wave device with suppressed excitation of spurious waves. The surface acoustic wave device comprises: a support substrate; a piezoelectric layer formed on the support substrate; and an IDT electrode on the piezoelectric layer, wherein when a wavelength of a surface acoustic wave excited at the IDT electrode is λ, thickness of the piezoelectric layer is 2.4λ or less.

### BACKGROUND OF THE INVENTION

### Field of the Invention

The present invention relates to a surface acoustic wave device that combines a piezoelectric layer and a substrate to suppress excitation of spurious waves.

### Background of the Related Art

A Surface Acoustic Wave (SAW) refers to a wave that propagates along the surface of an elastic solid, and the surface acoustic wave propagates with energy concentrated near the surface and corresponds to a mechanical wave. The surface acoustic wave device is an electromechanical device that utilizes interactions between the surface acoustic waves and conduction electrons, and uses surface acoustic waves transferred to the surface of a piezoelectric crystal. The surface acoustic wave device may have a very wide range of industrial applications including sensors, oscillators, filters, and the like, and may be miniaturized and lightweighted to have various advantages such as robustness, stability, sensitivity, low cost, real-time property, and the like.

Patent Document 1 discloses a structure of bonding a sapphire substrate to a piezoelectric layer made of LiTaO₃, and proposes a structure in which T/t<1/3 when the thickness of the piezoelectric layer is T and the thickness of the sapphire substrate is t, and T/λ>10 when the wavelength of the surface wave is λ. In this structure, when T/λ is not equal to or larger than 10, the spurious amplitude is considered large.
(Patent Document 1) U.S. Pat. No. 6,933,810B2

### SUMMARY OF THE INVENTION

Therefore, the present invention has been made in view of the above problems, and it is an object of the present invention to provide a configuration that suppresses excitation of spurious waves in a surface acoustic wave device combining a piezoelectric layer and a substrate.

The technical problems of the present invention are not limited to the technical problems mentioned above, and unmentioned other technical problems will be clearly understood by those skilled in the art from the following description.

To accomplish the above object, according to one aspect of the present invention, there is provided a surface acoustic wave device comprising: a support substrate; and a piezoelectric layer formed on the support substrate, wherein thickness of the piezoelectric layer is 2.4λ or less.

In some embodiments of the invention, the support substrate may include a sapphire substrate, and the piezoelectric layer may include LiTaO₃.

In some embodiments of the invention, the sapphire substrate is a C-plane, and when a propagation direction of the surface acoustic wave is Euler angles (0, 0, Θ), Θ may be a multiple of 0° or 60°, and the thickness of the piezoelectric layer may be 0.15λ or more and 0.30λ or less.

In some embodiments of the invention, the thickness of the piezoelectric layer may be 0.20λ or more and 0.30λ or less.

In some embodiments of the invention, a cutting angle of the piezoelectric layer may be 15° Y or more and 52°Y or less.

In some embodiments of the invention, the cutting angle of the piezoelectric layer may be 20° Y or more and 50° Y or less.

In some embodiments of the invention, the sapphire substrate may be an A-plane, and when a propagation direction of the surface acoustic wave is Euler angles (0, 90°, Θ), Θ may be 0° or 180°, and the thickness of the piezoelectric layer may be 0.30λ or more.

In some embodiments of the invention, the thickness of the piezoelectric layer may be 0.35λ or more.

In some embodiments of the invention, the sapphire substrate may be an A-plane, and when a propagation direction of the surface acoustic wave is Euler angles (0, 90°, Θ), Θ may be 90° or 270°.

In some embodiments of the invention, the thickness of the piezoelectric layer may be 0.30λ or more.

In some embodiments of the invention, the thickness of the piezoelectric layer may be 0.35λ or more.

In some embodiments of the invention, the sapphire substrate may be an R-plane, and when a propagation direction of the surface acoustic wave of the sapphire substrate is Euler angles (60°, 57.6°, Θ), Θ may be 0, 90°, 180°, or 270°, and the thickness of the piezoelectric layer may be 0.30λ or more.

In some embodiments of the invention, the thickness of the piezoelectric layer may be 0.34λ or more.

According to the surface acoustic wave device of the present invention, the intensity of excitation of spurious waves can be suppressed, and the number of excitations may also be kept low.

The effects of the present invention are not limited to the effects mentioned above, and unmentioned other effects will be clearly understood by those skilled in the art from the description of the claims.

### BRIEF DESCRIPTION OF THE DRAWINGS

FIG. 1 is a view showing a SAW resonator.

FIG. 2 is a view showing a result of simulating the admittance characteristics of a SAW resonator according to the prior art.

FIG. 3 is a view showing a result of simulating the admittance characteristics of the SAW resonator of FIG. 1 when the thickness of the piezoelectric layer is set to 20λ in the SAW resonator.

FIG. 4 is a view showing a result of simulating the admittance characteristics of the SAW resonator of FIG. 1 when the thickness of the piezoelectric layer is set to 1λ in the SAW resonator.

FIG. 5 is a view showing a result of simulating the admittance characteristics and conductance characteristics of a SAW resonator when the thickness of the piezoelectric layer is set to 0.1λ.

FIG. 6 is a graph calculating the relation between the thickness of the piezoelectric layer and the minimum conductance value near the anti-resonance frequency.

FIGS. 7A and 7B are graphs showing the admittance characteristics and conductance characteristics of a SAW resonator when the thickness of the piezoelectric layer is 2λ and 1λ, respectively.

FIG. 8 is a graph showing the bulk wave sound velocity of a C-plane sapphire substrate.

FIG. 9 is a view showing comparison of the admittance characteristics of a SAW resonator when the slow transverse wave sound velocity of the C-plane sapphire substrate is the lowest (0, 0, 0) and when the slow transverse wave sound velocity is the highest (0,0,30).

FIG. 10 is a view showing the admittance characteristics of a SAW resonator calculated as a function of varying the thickness of the piezoelectric layer when the Euler angle of the C-plane sapphire substrate is set to (0, 0, 0).

FIG. 11 is graphs showing calculated magnitudes of sound velocity, electromechanical coupling coefficient, and amplitude as a function of the thickness of the piezoelectric layer in the main mode, plate mode, and Rayleigh wave mode having the admittance characteristics of a surface acoustic wave device of the present invention.

FIG. 12 is a graph showing the bulk wave sound velocity of an A-plane sapphire substrate.

FIG. 13 is a graph showing the admittance characteristics of a SAW resonator calculated as a function of varying the thickness of the piezoelectric layer when the Euler angle of the A-plane sapphire substrate is set to (0, 90°, 0).

FIG. 14 is graphs showing calculated magnitudes of sound velocity, electromechanical coupling coefficient, and amplitude as a function of the thickness of the piezoelectric layer in the main mode, plate mode, and Rayleigh wave mode having the admittance characteristics of a surface acoustic wave device of the present invention.

FIG. 15 is a graph showing the admittance characteristics of a SAW resonator calculated when the thickness of the piezoelectric layer is changed in the case where the A-plane sapphire substrate rotates the propagation direction of the SAW by 90° to 270°.

FIG. 16 is graphs showing calculated magnitudes of sound velocity, electromechanical coupling coefficient, and amplitude as a function of the thickness of the piezoelectric layer in the main mode, plate mode, and Rayleigh wave mode having the admittance characteristics of a surface acoustic wave device of the present invention.

FIG. 17 is a graph showing the bulk wave sound velocity of an R-plane sapphire substrate.

FIG. 18 is a graph showing the admittance characteristics of a SAW resonator calculated as a function of varying the thickness of the piezoelectric layer when the Euler angle of the A-plane sapphire substrate is set to (60°, 57.4°, 0).

FIG. 19 is graphs showing calculated magnitudes of sound velocity, electromechanical coupling coefficient, and amplitude as a function of the thickness of the piezoelectric layer in the main mode, plate mode, and Rayleigh wave mode having the admittance characteristics of a surface acoustic wave device of the present invention.

FIG. 20 is a graph showing the admittance characteristics of a SAW resonator calculated when the orientation of the piezoelectric layer is changed in the case where the C-plane sapphire substrate is set to (0, 0, 0).

FIG. 21 is graphs showing calculated magnitudes of sound velocity, electromechanical coupling coefficient, and amplitude as a function of the thickness of the piezoelectric layer in the main mode, plate mode, and Rayleigh wave mode having the admittance characteristics of a surface acoustic wave device of the present invention.

### DETAILED DESCRIPTION OF THE PREFERRED EMBODIMENT

The advantages and features of the present invention and the method for achieving them will become clear by referring to the embodiments described below in detail together with the accompanying drawings. However, the present invention is not limited to the embodiments disclosed below and will be implemented in various different forms. The embodiments are provided only to make the disclosure of the present invention complete and to fully inform those skilled in the art of the scope of the present invention, and the present invention is only defined by the scope of the claims. Like reference numerals refer to like elements throughout the specification.

“And/or” includes each of the mentioned items and all combinations of one or more of the mentioned items.

The terms used in this specification are intended to describe the embodiments and are not to limit the present invention. In this specification, singular forms also include plural forms unless specially stated otherwise in the phrases. The terms “comprises” and/or “comprising” used in this specification means that the mentioned components, steps, operations, and/or elements do not exclude the presence or addition of one or more other components, steps, operations and/or elements.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specially defined.

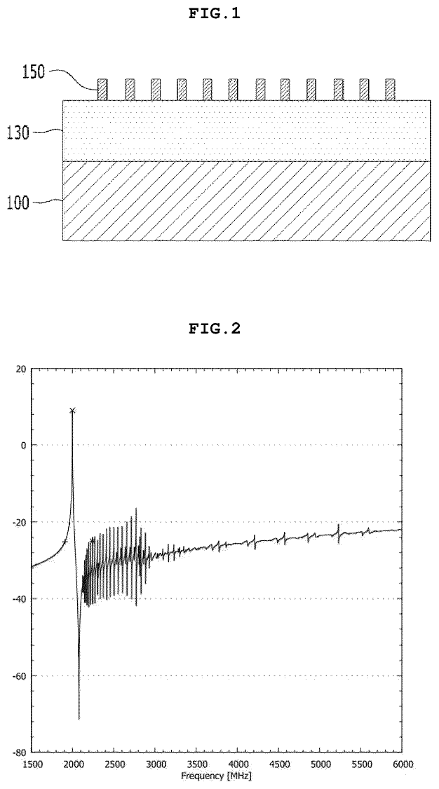

FIG. 1 is a view showing a SAW resonator, and FIG. 2 is a view showing a result of simulating the admittance characteristics of a SAW resonator according to the prior art.

Referring to FIG. 1, a piezoelectric layer 130 including LiTaO₃ propagates at 42° YcutX and has a thickness of 10λ. A support substrate 100 including sapphire is C-plane, and the propagation direction is the A-plane direction. That isthe Eulter angle is set to (0,0,0).

An IDT electrode 150 includes aluminum, and the thickness standardized to the wavelength of the surface acoustic wave is 7%. The pitch of the IDT electrode 150 is 1 μm, and the wavelength λ of the surface acoustic wave is 2 μm. The duty factor of the IDT electrode 150 is 0.5. As shown in FIG. 2, in addition to the main resonance around 2 Ghz, a spurious response appears in a range of about 2.1 GHz to about 3 GHZ.

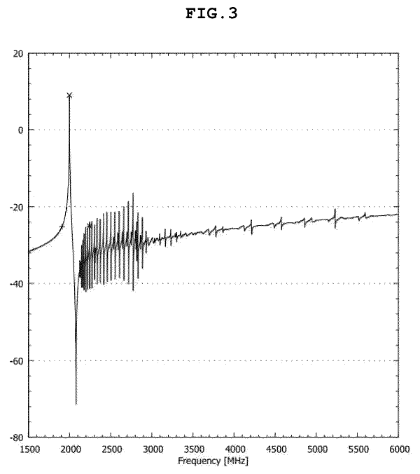

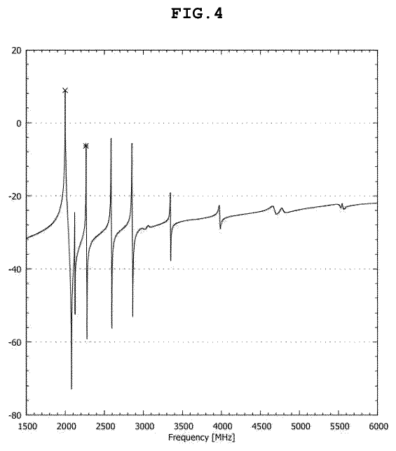

FIG. 3 is a view showing a result of simulating the admittance characteristics of the SAW resonator of FIG. 1 when the thickness of the piezoelectric layer 130 is set to 20λ in the SAW resonator. Referring to FIG. 3, it can be seen that compared to a case where the thickness of the piezoelectric layer 130 shown in FIG. 2 is 10λ, the amplitude of the spurious wave is lowered, and the frequency interval of the spurious wave is also reduced.

FIG. 4 is a view showing a result of simulating the admittance characteristics of the SAW resonator of FIG. 1 when the thickness of the piezoelectric layer 130 is set to 1λ in the SAW resonator. As shown in FIG. 4, it can be seen that the thinner the thickness of the piezoelectric layer 130, the amplitude of the spurious waves increases, but the frequency interval of the spurious waves narrows.

When the thickness of the piezoelectric layer 130 is reduced to be smaller than 1λ, since the sound velocity of the wafer of the support substrate 100 is higher than the sound velocity of the surface acoustic wave of the piezoelectric layer 130, the effect of trapping the SAW energy in the piezoelectric layer 130 begins to appear.

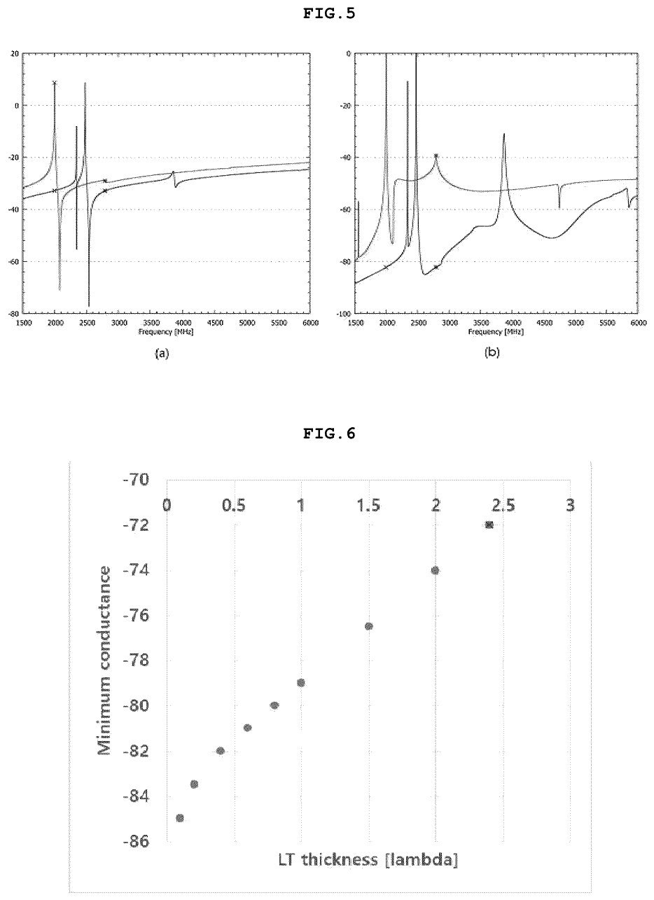

FIG. 5 is a view showing a result of simulating the admittance characteristics (a) and conductance characteristics (b) of a SAW resonator when the thickness of the piezoelectric layer 130 is set to 0.1λ. Like the SAW resonator of FIG. 1, the stacking structure of the piezoelectric layer and the support substrate is shown as a blue graph, and the result of the single structure of the piezoelectric layer is shown as a red graph.

Referring to FIG. 5, the loss performance of the SAW resonator is determined as the conductance characteristic near the resonance frequency and anti-resonance frequency of the SAW resonator. In the vicinity of the anti-resonance frequency, the smaller the conductance, the smaller the loss. In the case of a single piezoelectric layer structure, the minimum conductance value near the anti-resonance frequency is −72 dB, and in the case of the stacking structure of the piezoelectric layer and the support substrate, the minimum conductance value is −85 dB.

In addition, the SAW excited at the cut angle of the single piezoelectric layer structure is the so-called leaky SAW, and the conductance value and the loss appear to be large due to radiation of bulk waves in the substrate depth direction in a region of a frequency higher than the anti-resonance frequency.

On the other hand, in the stacking structure of the piezoelectric layer and the support substrate, since the lowest transverse wave velocity of the support substrate is 5, 751 m/s and the sound velocity of the SAW at this point is 4900 m/s or higher, as radiation of the bulk waves in the substrate depth direction is suppressed. It can be seen that the conductance value is small throughout the entire frequency range from the frequency near the anti-resonance frequency to 6 GHz.

FIG. 6 is a graph calculating the relation between the thickness of the piezoelectric layer and the minimum conductance value near the anti-resonance frequency. The horizontal axis represents thickness of the piezoelectric layer in A, and the vertical axis represents the conductance value.

Referring to FIG. 6, when the thickness of the piezoelectric layer is 2.4λ or more, the minimum conductance value (−72 dB) of the single piezoelectric layer structure is the same as that of the stacking structure of the piezoelectric layer and the support substrate. That is, it can be seen that the effect of suppressing radiation of bulk waves of leaky SAW begins to occur when the LT thickness is 2.4λ or less.

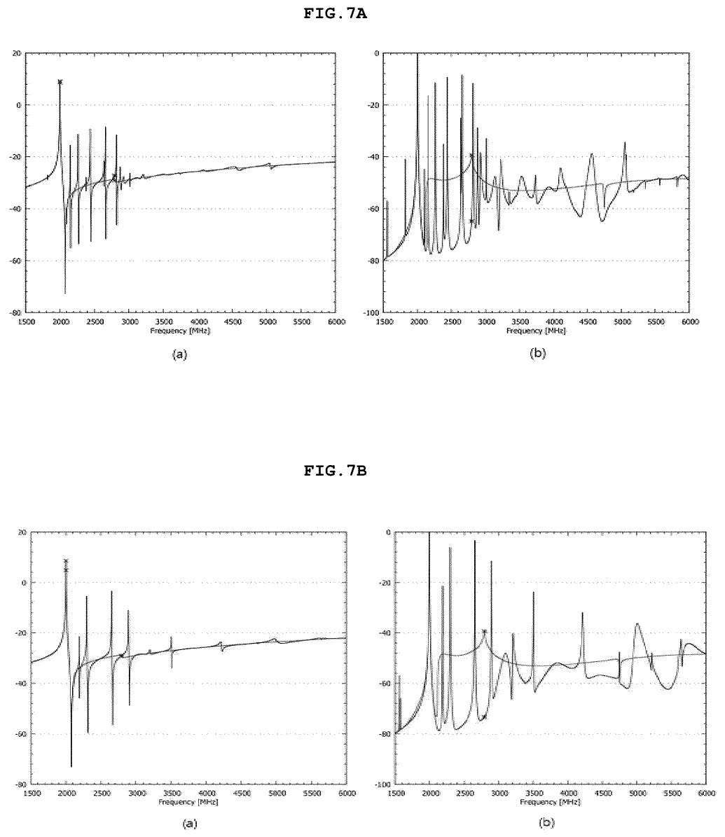

FIGS. 7A and 7B are graphs showing the admittance characteristics (a) and conductance characteristics (b) of a SAW resonator when the thickness of the piezoelectric layer is 2λ and 1λ, respectively. Referring to FIGS. 7A and 7B, in a way the same as described above, the stacking structure of the piezoelectric layer and the support substrate is shown as a blue graph, and the result of the structure of the single piezoelectric layer is shown as a red graph.

As described above, it can be seen that the conductance and loss are small near the anti-resonance frequency when the thickness of the piezoelectric layer is 2.4λ or less, but a great large amount of spurious excitation is generated. The spurious waves are mainly generated by Reyleigh wave generated on the surface of the piezoelectric layer, by the combination of slow longitudinal bulk waves of the sapphire substrate and the electric field excited at the IDT electrode, by the combination of slow transverse bulk waves of the sapphire substrate and the electric field excited at the IDT electrode, or the combination of fast transverse bulk waves of the sapphire substrate and the electric field excited at the IDT electrode. Other spurious waves are higher-order modes of the spurious waves generated as described above or are generated by combining two or more of those, but as their amplitude is generally smaller than that of the base wave mode, they do not make a big problem.

When a single crystal sapphire substrate is used, the sound velocity of the bulk waves varies according to the cutting direction. Therefore, the frequency of generating the spurious waves may vary according to the cutting direction, and three types of sapphire substrates including C-plane, A-plane, and R-plane are currently distributed in the industry. The propagation direction of the surface acoustic waves on the wafer may be selected at the time of stacking the wafer.

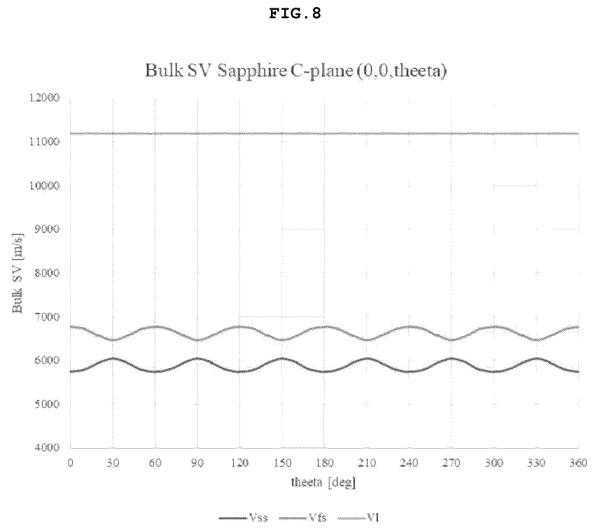

FIG. 8 is a graph showing the bulk wave sound velocity of a C-plane sapphire substrate.

Referring to FIG. 8, the horizontal axis represents the propagation direction of the surface acoustic wave in a sapphire substrate, and the Euler angle is set to (0, 0, Θ).

In the graph of FIG. 8, VI is the fastest longitudinal wave, Vfs is the fast transverse wave, and Vss is the slow transverse wave. It can be seen that due to the crystal symmetry of the sapphire substrate, the sound velocities of the transverse waves are equal at the cycle of 60°, and the velocity of the slow transverse wave is 0°, which is lowest at the multiples of 60°.

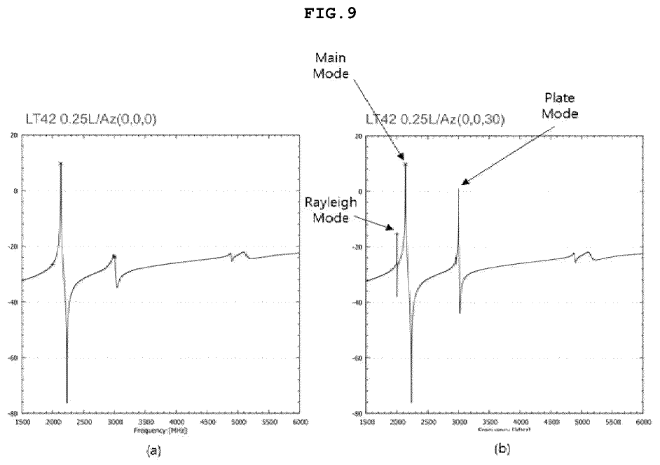

FIG. 9 is a view showing comparison of the admittance characteristics of a SAW resonator when the slow transverse wave sound velocity of the C-plane sapphire substrate is the lowest (0,0,0) and when the slow transverse wave sound velocity is the highest (0,0,30).

The orientation of the piezoelectric layer is 42° YX propagation, and the thickness of the piezoelectric layer is 0.25λ. λ of the IDT electrode is 2 μm, the duty factor is 0.5, the material of the IDT electrode is aluminum, and the thickness of the IDT electrode standardized to λ is 7%.

As shown in FIG. 9, the spurious wave response when the orientation of the sapphire substrate is (0, 0, 0) (FIG. 9(a)) is significantly different from the spurious wave response when the orientation of the sapphire substrate is (0, 0, 30°) (FIG. 9(b)). The spurious wave response of the Rayleigh wave mode exists around 2.1 GHZ under the main mode resonance frequency, and the spurious wave response of the plate mode exists around 3 GHz. It can be seen that the responses of the Rayleigh wave mode and the plate mode are large when the orientation of the sapphire substrate is (0, 0, 30°), but the responses can be suppressed small when the orientation is (0, 0, 0).

In relation to the plate mode, the slow transverse wave velocity of the sapphire substrate is 5751 m/s in the case of (0, 0, 0), but it is as high as 6052 m/s in the case of (0, 0, 30°). Therefore, in the case of (0, 0, 0), since the wavelength λ of the elastic wave generated from the IDT electrode is 2 μm, when the frequency of the plate mode is 5751/2=2875.5 MHz or less, the SAW energy of the plate mode is confined to the piezoelectric layer, and the amplitude of the plate mode increases. On the other hand, in the case of (0, 0, 30°) and the frequency of the plate mode is lower than 3026 MHz, the SAW energy of the plate mode is confined to the piezoelectric layer, and the amplitude of the plate mode increases.

In this way, the plate mode amplitude changes greatly according to the frequency of occurrence of the plate mode and the slow transverse wave velocity of the sapphire substrate, and the frequency of occurrence of the plate mode may be determined by the distance from the piezoelectric layer to the sapphire substrate, i.e., the thickness of the piezoelectric layer.

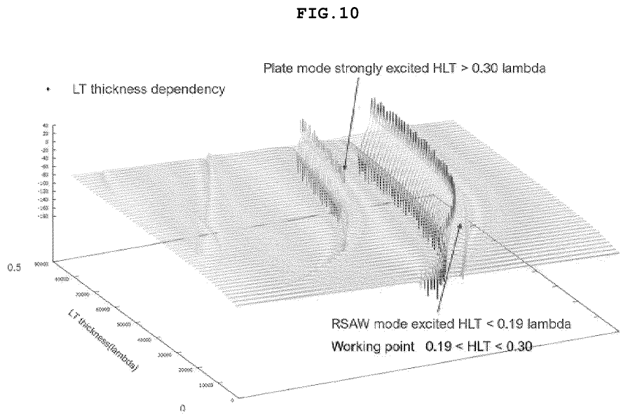

FIG. 10 is showing a view the admittance characteristics of a SAW resonator calculated as a function of varying the thickness of the piezoelectric layer when the Euler angle of the C-plane sapphire substrate is set to (0, 0, 0). The orientation of the piezoelectric layer is 42° YX propagation, and the thickness of the piezoelectric layer is 0.25λ. A of the IDT electrode is 2 μm, the duty factor is 0.5, the material of the IDT electrode is aluminum, and the thickness of the IDT electrode standardized to λ is 7%. A result calculated using the thickness of the piezoelectric layer as a parameter in a range of 0 to 0.5λ is shown.

As shown in FIG. 10, it can be seen that the responses of the plate mode and Rayleigh wave mode vary greatly according to the thickness of the piezoelectric layer.

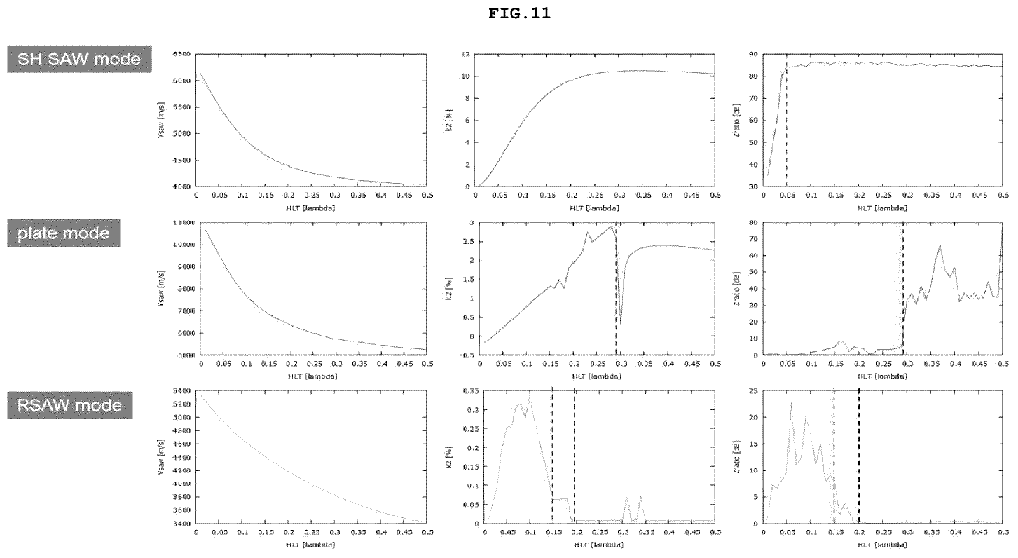

FIG. 11 is graphs showing calculated magnitudes of sound velocity Vsaw, electromechanical coupling coefficient k2, and amplitude Zratio as a function of the thickness of the piezoelectric layer in the main mode, plate mode, and Rayleigh wave mode having the admittance characteristics of a surface acoustic wave device of the present invention.

In the main mode, a sufficiently large amplitude Zratio can be obtained when the thickness of the piezoelectric layer is 0.05λ or more. In the plate mode, the amplitude can be reduced when the thickness of the piezoelectric layer is 0.30λ or less, and in the Rayleigh wave mode, the amplitude can be reduced when the thickness of the piezoelectric layer is 0.15λ or more, preferably 0.2λ or more.

In this way, when the Euler angles of the C-plane sapphire substrate are (0, 0, 0), a surface acoustic wave resonator having a small amplitude of the plate mode and Rayleigh wave mode can be realized by setting the thickness of the piezoelectric layer to 0.15λ or more and 0.30 or less.

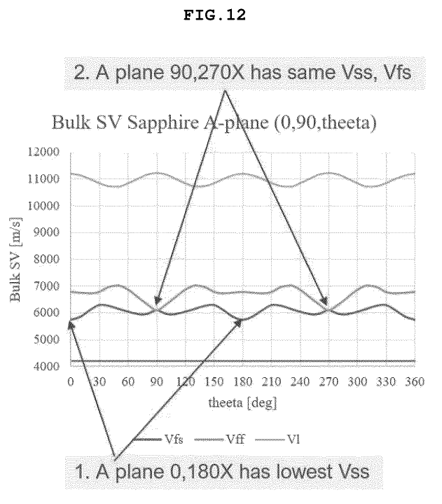

FIG. 12 is a graph showing the bulk wave sound velocity of an A-plane sapphire substrate. The horizontal axis represents the propagation direction of the surface acoustic wave in the sapphire substrate, and the Euler angles is set to (0, 90°, Θ).

Referring to FIG. 12, in the case of A-plane, there are two interesting propagation directions. When Θ is 0 or 180°, the velocity of the slow transverse wave becomes the lowest, and when Θ is 90° or 270°, the velocities of the slow and fast transverse waves are the same. When the velocities of the slow and fast transverse waves are the same, the number of modes generating the waves is smaller than the number of modes when the velocities are different.

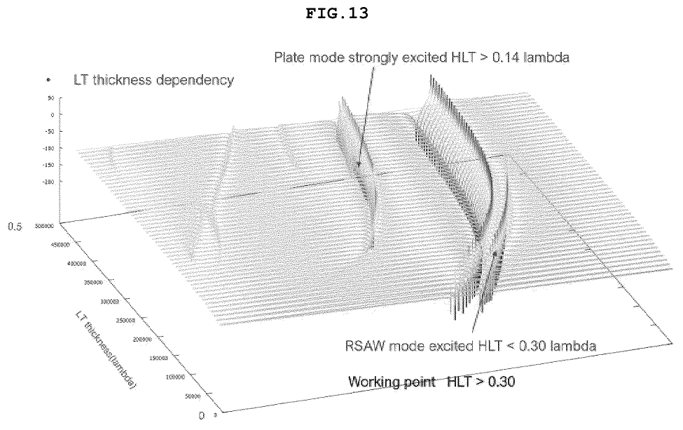

FIG. 13 is a graph showing the admittance characteristics of a SAW resonator calculated as a function of varying the thickness of the piezoelectric layer when the Euler angle of the A-plane sapphire substrate is set to (0, 90°, 0). The orientation of the piezoelectric layer is 42° YX propagation, λ of the IDT electrode is 2 μm, the duty factor is 0.5, the material of the IDT electrode is aluminum, and the thickness of the IDT electrode standardized to λ is 7%. This is a result calculated using the thickness of the piezoelectric layer as a parameter in a range of 0 to 0.5λ.

Compared with a case where the sapphire substrate is C-plane (FIG. 10), it can be seen that the thickness conditions of the piezoelectric layer for generating the plate mode and Rayleigh wave mode are different.

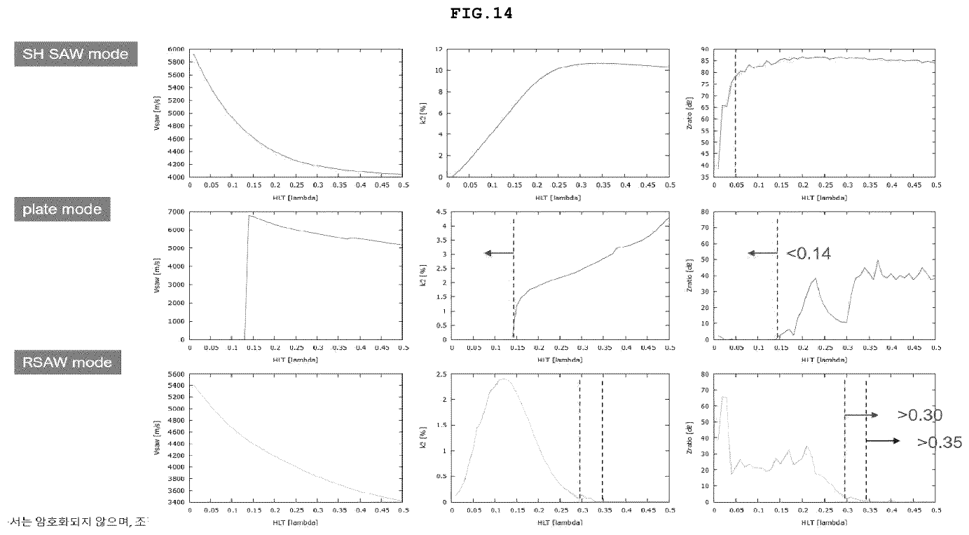

FIG. 14 is graphs showing calculated magnitudes of sound velocity Vsaw, electromechanical coupling coefficient k2, and amplitude Zratio as a function of the thickness of the piezoelectric layer in the main mode, plate mode, and Rayleigh wave mode having the admittance characteristics of a surface acoustic wave device of the present invention.

In the main mode, like in the case of C-plane, a sufficiently large amplitude Zratio can be obtained when the thickness of the piezoelectric layer is 0.05λ or more. In the plate mode, the amplitude can be reduced when the thickness of the piezoelectric layer is 0.14λ or less, and in the Rayleigh wave mode, the amplitude can be reduced when the thickness of the piezoelectric layer is 0.30) or more, preferably 0.35λ or more.

In summary, when the sapphire substrate is A-plane and the Euler angles are (0, 90°, 0) or (0, 90°, 180°), an orientation of the sapphire substrate that can simultaneously suppress the plate mode and the Rayleigh wave mode does not exist. However, when a filter or a multiplexer is configured using a surface acoustic wave resonator, as the Rayleigh wave mode having a sound velocity close to that of the main mode may generate spikes in the pass band of the filter or multiplexer, in implementing the filter, it is more important than the plate mode with reduced velocity of sound.

Therefore, when the Euler angles of the A-plane sapphire substrate are (0, 90°, 0) or (0, 90°, 180°), a surface acoustic wave resonator having a small amplitude of the Rayleigh wave mode can be implemented by setting the thickness of the piezoelectric layer to 0.30λ or more, preferably to 0.35λ or more.

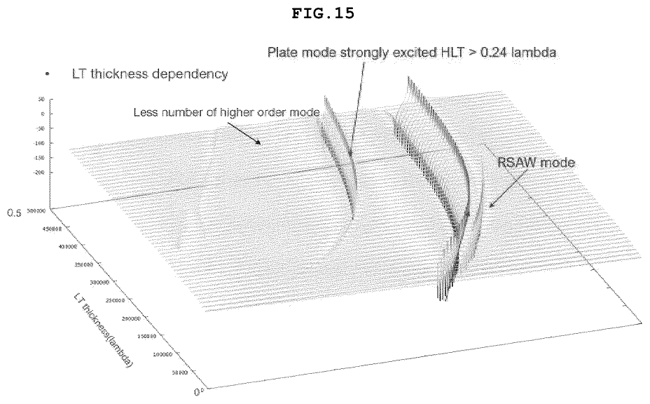

FIG. 15 is a graph showing the admittance characteristics of a SAW resonator calculated when the thickness of the piezoelectric layer is changed in the case where the A-plane sapphire substrate rotates the propagation direction of the SAW by 90° to 270°, i.e., the Euler angle is set to (0, 90°, 90°) or (0, 90°, 270°). The orientation of the piezoelectric layer is 42° YX propagation, λ of the IDT electrode is 2 μm, the duty factor is 0.5, the material of the IDT electrode is aluminum, and the thickness of the IDT electrode standardized to λ is 7%. This is a result calculated using the thickness of the piezoelectric layer as a parameter in a range of 0 to 0.5λ.

Even in the case of FIG. 15, it can be seen that the frequency and amplitude at which the plate mode and the Rayleigh wave mode occur are different. In the first-order plate mode, it is strongly excited when the thickness of the piezoelectric layer exceeds 0.22λ, and since the bulk wave sound velocities of the slow and fast transverse waves are the same in this sapphire substrate, it can be seen that the number of plate modes of an order higher than that of the first plate mode is small compared to (0, 90°, 0) of A-plane.

When the first-order plate mode satisfies the required characteristics of the filter, the feature of a small number of higher-order spurious wave modes is advantageous for the attenuation characteristics of the filter.

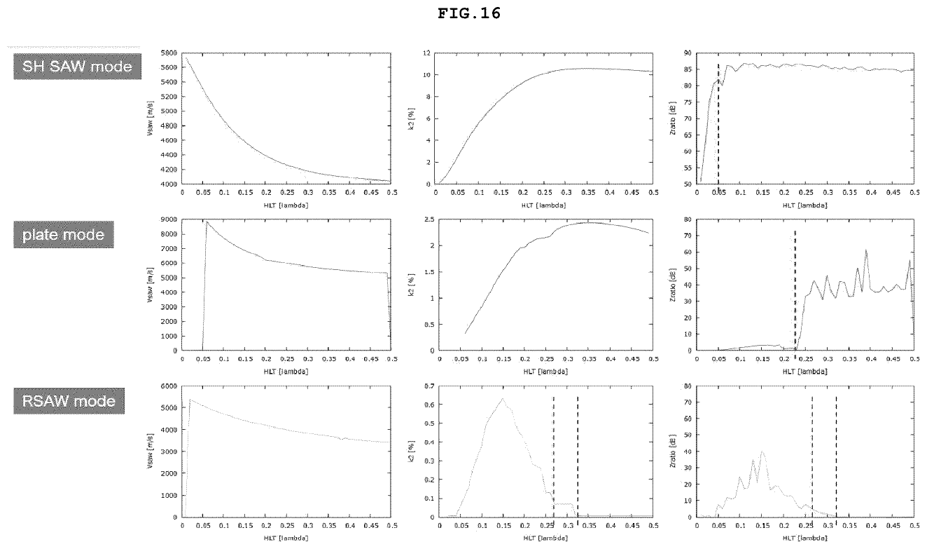

FIG. 16 is graphs showing calculated magnitudes of sound velocity Vsaw, electromechanical coupling coefficient k2, and amplitude Zratio as a function of the thickness of the piezoelectric layer in the main mode, plate mode, and Rayleigh wave mode having the admittance characteristics of a surface acoustic wave device of the present invention.

In the main mode, like in the case of C-plane, a sufficiently large amplitude Zratio can be obtained when the thickness of the piezoelectric layer is 0.05λ or more. In the plate mode, the amplitude can be reduced when the thickness of the piezoelectric layer is 0.24λ or less, and in the Rayleigh wave mode, the amplitude can be reduced when the thickness of the piezoelectric layer is 0.30λ or more, preferably 0.32λ or more.

In summary, when the sapphire substrate is A-plane and the Euler angles are (0, 90°, 90°) or (0, 90°, 270°), an orientation of the sapphire substrate that can simultaneously suppress the plate mode and the Rayleigh wave mode does not exist. However, when a filter or a multiplexer is configured using a surface acoustic wave resonator, as the Rayleigh wave mode having a sound velocity close to that of the main mode may generate spikes in the pass band of the filter or multiplexer, it is more important than the plate mode with reduced velocity of sound in implementing the filter.

Therefore, when the Euler angles of the A-plane sapphire substrate are (0, 90°, 90°) or (0, 90°, 270°), a surface acoustic wave resonator having a small amplitude of the Rayleigh wave mode can be implemented by setting the thickness of the piezoelectric layer to 0.30λ or more, preferably to 0.32λ or more. In addition, this surface acoustic wave resonator has a characteristic of a small number of high-order plate modes.

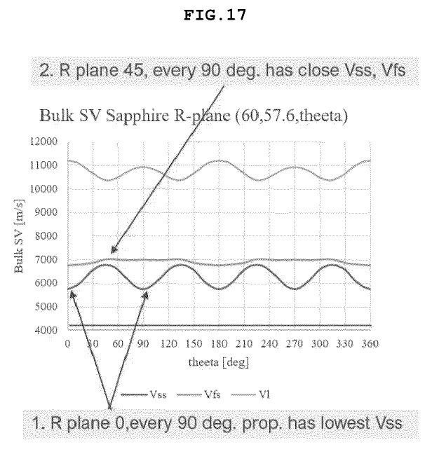

FIG. 17 is a graph showing the bulk wave sound velocity of an R-plane sapphire substrate. The horizontal axis represents the propagation direction of the surface acoustic wave in the sapphire substrate, and the propagation direction is (60°, 57.6°, Θ) in terms of Euler angles.

Referring to FIG. 17, in the case of R-plane, there are two interesting propagation directions. When Θ is 0 or 90°, the velocity of the slow transverse wave becomes the lowest, and when Θ is a multiple angle of 90°, the velocities of the slow transverse waves come to be equal. In addition, when Θ is 45°, 135°, 225°, and 315°, the velocities of slow and fast transverse waves become close to each other, and the number of occurrences of the plate mode does not decrease, but the frequency of occurrence comes to be close.

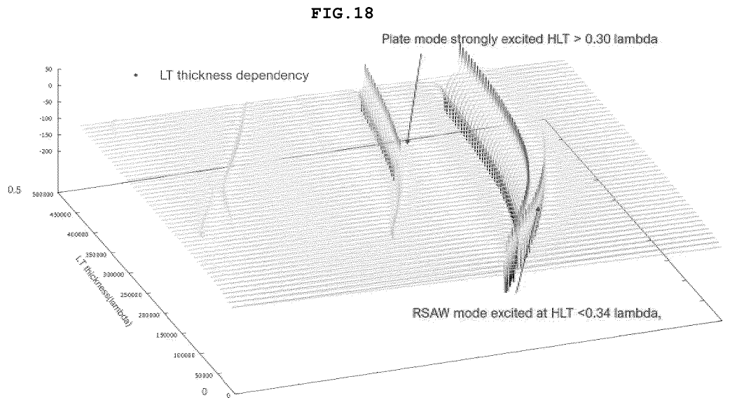

FIG. 18 is a graph showing the admittance characteristics of a SAW resonator calculated as a function of varying the thickness of the piezoelectric layer when the Euler angle of the A-plane sapphire substrate is set to (60°, 57.4°, 0). The orientation of the piezoelectric layer is 42° YX propagation, λ of the IDT electrode is 2 μm, the duty factor is 0.5, the material of the IDT electrode is aluminum, and the thickness of the IDT electrode standardized to λ is 7%. This is a result calculated using the thickness of the piezoelectric layer as a parameter in a range of 0 to 0.5λ.

When the sapphire substrate is R-plane, the excitation characteristics of each mode are similar to those of the C-plane.

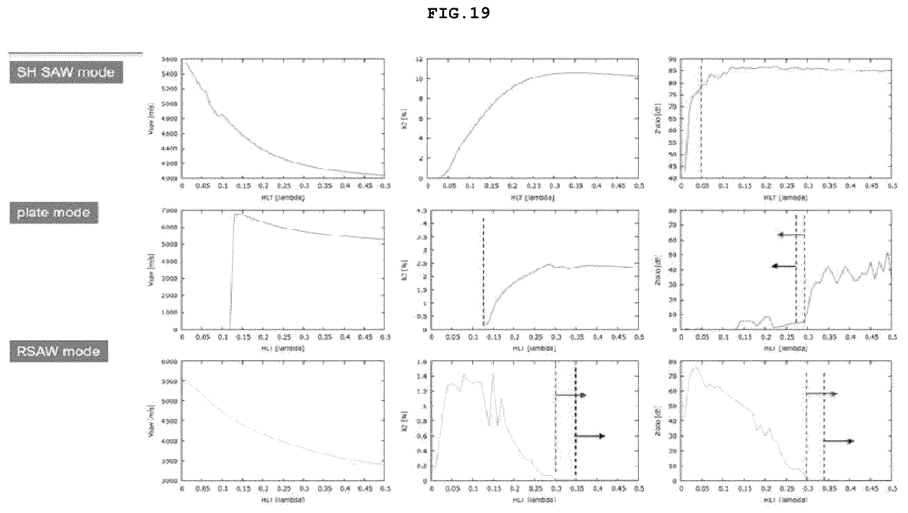

FIG. 19 is graphs showing calculated magnitudes of sound velocity, electromechanical coupling coefficient, and amplitude as a function of the thickness of the piezoelectric layer in the main mode, plate mode, and Rayleigh wave mode having the admittance characteristics of a surface acoustic wave device of the present invention.

In the main mode, like in the case of C-plane, a sufficiently large amplitude Zratio can be obtained when the thickness of the piezoelectric layer is 0.05λ or more. In the plate mode, the amplitude can be reduced when the thickness of the piezoelectric layer is 0.30λ or less, and in the Rayleigh wave mode, the amplitude can be reduced when the thickness of the piezoelectric layer is 0.30λ or more, preferably 0.34λ or more.

In summary, when the sapphire substrate is R-plane and the Euler angles are (60°, 57.6°, 0°), (60°, 57.6°, 90°), (60°, 57.6°, 180°), or (60°, 57.6°, 270°), an orientation of the sapphire substrate that can simultaneously suppress the plate mode and the Rayleigh wave mode does not exist. However, when a filter or a multiplexer is configured using a surface acoustic wave resonator, as the Rayleigh wave mode having a sound velocity close to that of the main mode may generate spikes in the pass band of the filter or multiplexer, it is more important than the plate mode with reduced velocity of sound in implementing the filter.

Therefore, when the Euler angles of the R-plane sapphire substrate are (60°, 57.6°, 0°), (60°, 57.6°, 90°), (60°, 57.6°, 180°), or (60°, 57.6°, 270°), a surface acoustic wave resonator having a small amplitude of the Rayleigh wave mode can be implemented by setting the thickness of the piezoelectric layer to 0.30λ or more, preferably to 0.34λ or more.

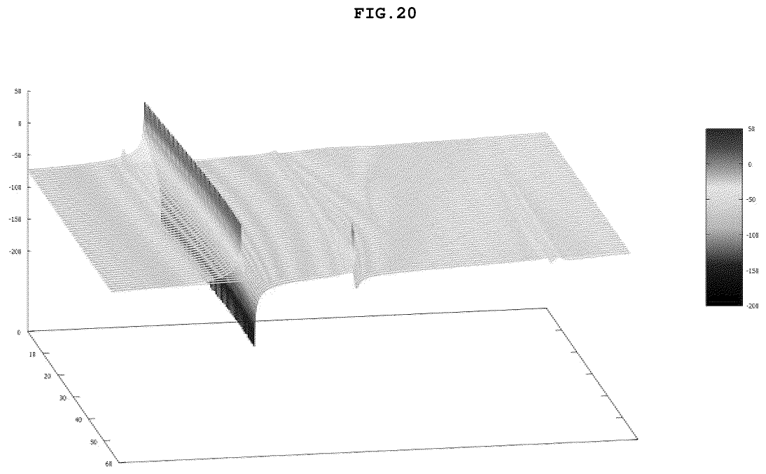

FIG. 20 is a graph showing the admittance characteristics of a SAW resonator calculated when the orientation of the piezoelectric layer is changed in the case where the C-plane sapphire substrate is set to (0, 0, 0). The cutting angle of the piezoelectric layer is set to a rotating Y plate, the propagation direction of the surface acoustic wave is the X direction of the piezoelectric layer, A of the IDT electrode is 2 μm, the duty factor is 0.5, the material of the IDT electrode is aluminum, and the thickness of the IDT electrode standardized to λ is 7%. It is calculated in a range of 0 to 55° using the cutting angle of the piezoelectric layer as a parameter.

As shown in FIG. 20, it can be seen that although the cutting angle of the piezoelectric layer changes, the change in the Rayleigh wave mode and the plate mode is small. Therefore, it is possible to suppress the Rayleigh wave mode and the plate mode in a wide Y-cut range.

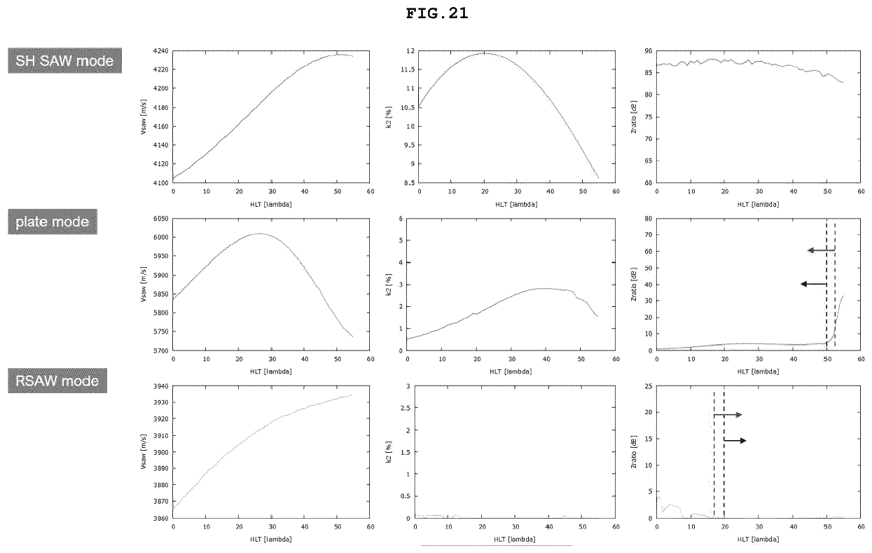

FIG. 21 is graphs showing calculated magnitudes of sound velocity, electromechanical coupling coefficient, and amplitude as a function of the thickness of the piezoelectric layer in the main mode, plate mode, and Rayleigh wave mode having the admittance characteristics of a surface acoustic wave device of the present invention.

In the main mode, the electromechanical coupling coefficient is the largest around 20° Y, and its Zratio gradually decreases as the cutting angle increases, but as it appears very large as much as over 80 dB between 0 and 55° Y, a low-loss filter can be implemented at any cutting angle.

For the plate mode, the amplitude becomes small at 52° Y or less, preferably 50° Y or less, and for the Rayleigh wave mode, the amplitude becomes small at 15° Y or more, preferably 20° Y. Therefore, the Rayleigh wave mode and the plate mode can be suppressed when the cutting angle of the piezoelectric layer is 15° Y or more and 52° Y or less, preferably 20° Y or more and 50° Y or less.

Although the embodiments of the present invention have been described above with reference to the accompanying drawings, those skilled in the art may understand that the present invention can be implemented in other specific forms without changing the technical spirit or essential features. Therefore, the embodiments described above should be understood in all respects as illustrative and not restrictive.

### DESCRIPTION OF SYMBOLS

100: Support substrate
130: Piezoelectric layer
150: IDT electrode

What is claimed is:

1. A surface acoustic wave device comprising:
a support substrate;
a piezoelectric layer formed on the support substrate; and
an IDT electrode on the piezoelectric layer, wherein when a wavelength of a surface acoustic wave excited at the IDT electrode is λ, thickness of the piezoelectric layer is 2.4λ or less.

2. The device according to claim 1, wherein the support substrate includes a sapphire substrate, and the piezoelectric layer includes LiTaO₃.

3. The device according to claim 2, wherein the sapphire substrate is a C-plane, and when a propagation direction of the surface acoustic wave of the sapphire substrate is Euler angles (0, 0, Θ), Θ is a multiple of 0° or 60°, and the thickness of the piezoelectric layer is 0.15λ or more and 0.30λ or less.

4. The device according to claim 3, wherein the thickness of the piezoelectric layer is 0.20λ or more and 0.30λ or less.

5. The device according to claim 3, wherein a cutting angle of the piezoelectric layer is 15° Y or more and 52° Y or less.

6. The device according to claim 5, wherein the cutting angle of the piezoelectric layer is 20° Y or more and 50° Y or less.

7. The device according to claim 2, wherein the sapphire substrate is an A-plane, and when a propagation direction of the surface acoustic wave of the sapphire substrate is Euler angles (0, 90°, Θ), Θ is 0° or 180°, and the thickness of the piezoelectric layer is 0.30λ or more.

8. The device according to claim 7, wherein the thickness of the piezoelectric layer is 0.35λ or more.

9. The device according to claim 2, wherein the sapphire substrate is an A-plane, and when a propagation direction of the surface acoustic wave is Euler angles (0, 90°, Θ), Θ is 90° or 270°.

10. The device according to claim 9, wherein the thickness of the piezoelectric layer is 0.30λ or more.

11. The device according to claim 10, wherein the thickness of the piezoelectric layer is 0.35λ or more.

12. The device according to claim 2, wherein the sapphire substrate is an R-plane, and when a propagation direction of the surface acoustic wave of the sapphire substrate is Euler angles (60°, 57.6°, Θ), Θ is 0, 90°, 180°, or 270° and the thickness of the piezoelectric layer is 0.30λ or more.

13. The device according to claim 12, wherein the thickness of the piezoelectric layer is 0.34λ or more.
